(19) United States
(12) Patent Application Publication
(10) Pub. No.: US 2024/0215220 A1
(43) Pub. Date: Jun. 27, 2024

(54) INTEGRATED NANOSHEET MEMORY ELEMENTS, DEVICES AND METHODS

(71) Applicant: Tokyo Electron Limited, Tokyo (JP)

(72) Inventors: H. Jim Fulford, Marianna, FL (US); Mark I. Gardner, Cedar Creek, TX (US)

(21) Appl. No.: 18/509,560

(22) Filed: Nov. 15, 2023

Related U.S. Application Data
(60) Provisional application No. 63/434,389, filed on Dec. 21, 2022.

(51) Int. Cl. H10B 12/00

(52) U.S. Cl. CPC H10B 12/30; H10B 12/03; H10B 12/05

(57) ABSTRACT

A memory element and method of formation is disclosed that includes a transistor integrated with a capacitor through a common nanosheet. The transistor includes a channel, a source region, a drain region and a gate component on at least one side of the channel between the source region and drain region. The channel is formed in a first portion of a nanosheet. The capacitor has a first capacitor component and second capacitor component separated by an insulator. The first capacitor component is provided in a second portion of the nanosheet.

### CROSS REFERENCE TO RELATED PATENTS AND APPLICATIONS

The present application claims the benefit of U.S. Provisional Application No. 63/434,389 filed on Dec. 21, 2022, which is incorporated herein by reference in its entirety.

### BACKGROUND

In modern semiconductor integrated circuit devices, individual memory elements play an important role. Manufacturing such circuits usually relies on different fabrication processes, such as film-forming depositions, etch mask creation, patterning, material etching and removal, and doping treatments, many of which are performed repeatedly to form desired circuits on a substrate. Conventional fabrication techniques only manufacture memory circuits in one plane, while wiring or metallization can typically be formed above the active device plane. Devices manufacturing using these techniques are typically characterized as two-dimensional (2D) circuits. Although scaling efforts in 2D circuit fabrication have increased the number of transistors per unit area, 2D fabrication techniques remain limited as they are approaching physical atomic limitations with single digit nanometer semiconductor device fabrication nodes. Semiconductor device fabricators have expressed a desire for new solutions in addressing these challenges.

### SUMMARY

Three-dimensional (3D) integration can help alleviate limitations of 2D semiconductor device manufacturing by arranging semiconductor devices not only in the plane of the substrate (e.g., x-y directions), but also in the third dimension (e.g., z-direction), as well. Vertically stacking semiconductor devices can open new opportunities for semiconductor device manufacturers as 3D circuit fabrication can substantially increase the number of semiconductor circuits per unit area of a substrate.

Typical capacitor-based memory cells, including, for example, dynamic random-access memory (“DRAM”), have been implemented using 2D semiconductor techniques. As a single-bit DRAM cell typically includes a transistor and a capacitor, this circuit is normally implemented using a trench-based configuration, whereby a transistor is disposed on a substrate next to a corresponding capacitor. However, this 2D arrangement may not be conducive to stacking.

To reduce the amount of substrate surface needed to implement a DRAM cell, the present solution can provide a vertically-stacked 3D capacitor-based memory cell design in which a capacitor-based memory cell, such as a DRAM cell, can be implemented on a substrate space that is sufficient for only one memory element. Memory cells can be stacked vertically as multiple memory cells can utilize only the space required for a single memory cell even if the number of vertically-stacked memory cells are formed as a memory cell structure for 2-bit, 4-bit, 8-bit, 16-bit or more. In short, by stacking vertically upwards for a substrate surface, a smaller amount of substrate surface area is being used for more than one memory cell.

A memory element is disclosed that includes a transistor integrated with a capacitor through a common nanosheet. The transistor includes a channel, a source region, a drain region and a gate component on at least one side of the channel between the source region and drain region. The channel is provided in a first portion of a nanosheet. The capacitor has a first capacitor component and second capacitor component separated by an insulator. The first capacitor component is provided in a second portion of the nanosheet.

A method of formation of a memory element and corresponding memory device is provided in which a transistor component and capacitor component are provided in a common nanosheet. A transistor component is formed utilizing a first portion of the nanosheet. A capacitor component is formed utilizing a second portion of the nanosheet.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 shows a memory element device according to one implementation.

FIG. 2 shows a stage of device formation in which a stack of layers is provided with one or more nanosheet layers having a first dielectric layer on one or both sides.

FIG. 3 shows a stage of the device formation in which a nanosheet is defined from the nanosheet layer and a transistor component is formed utilizing a first portion of the nanosheet.

FIG. 4 shows a stage of the device formation in which the transistor is protected to leave exposed a second portion of the nanosheet.

FIG. 5 shows a stage of the device formation in which the second portion of the nanosheet is doped.

FIG. 6 shows a stage of the device formation in which a mask is provided to allow a portion of the nanosheet to be etched.

FIG. 7 shows a stage of the device formation in which a second dielectric layer is formed in the etched opening to separate the nanosheet into two sections as well as provide support for the nanosheet during subsequent steps.

FIG. 8 shows a stage of the device formation in which the first dielectric layer on one or both sides of the one or more nanosheets is removed.

FIG. 9 shows a stage of the device formation in which a third dielectric layer is formed on opposing sides of the one or more nanosheets.

FIG. 10 shows a stage of the device formation in which a metal layer is formed on the dielectric layer thereby finishing the capacitor component of the memory element.

### DETAILED DESCRIPTION

References will now be made to various illustrative embodiments depicted in the drawings, and specific language will be used to describe the same. It will nevertheless be understood that no limitation of the scope of the claims or this disclosure is thereby intended. Alterations and further modifications of the inventive features illustrated herein, and additional applications of the principles of the subject matter illustrated herein, which would be apparent to one of ordinary skill in the relevant art having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

It is understood that apparatuses, systems and devices produced by the structures described herein can be used or find their application in any number of electronic devices utilizing structures and/or circuits described herein, such as for example, controllers, memory chips, systems or process on a chip processor, graphics processing units, central processing units and more. For example, structures and/or circuits described herein can include a part of systems utilizing memory, such as any computing systems including for example: computers, phones, servers, cloud computing devices, and any other device or system that utilizes integrated circuit devices.

The embodiments described herein may enable an increased stack height of one or more 3D semiconductor devices such as memory elements. Therefore, a semiconductor substrate can be used, but is not required, and any base layer material (e.g., glass, organic, etc.) may be used instead of a traditional silicon substrate. A base layer, therefore, can be a semiconductor substrate, such as a silicon substrate.

The process flows described herein form NMOS and/or PMOS devices. Although illustrations herein may show an NMOS or PMOS device, alternative configurations may include a PMOS device over NMOS device (or vice versa), NMOS device over NMOS device, PMOS device over PMOS device, or other alternative including one or more NMOS devices or PMOS devices for any number of N stacks and in any order or arrangement.

Dielectric materials used herein can be any material or materials having low electrical conductivity, such as for example one millionth of a mho/cm. Dielectric materials can include, for example, silicon dioxide, silicon nitride, nanoporous silica, hydrogensilsesquioxanes (HSQ), Teflon-AF (polytetrafuoethene or PTFE), silicon oxyflouride. Dielectric materials can also include, for example, ceramics, glass, mica, organic and oxides of various metals.

High-k dielectric, also referred to as high k material, can refer to any material with a higher dielectric constant as compared to silicon dioxide. For example, high-k dielectric can include hafnium silicate, zirconium silicate, hafnium dioxide, zirconium dioxide, and others.

Various metals, such as gate metal and the source/drain metal, can be used herein and can include any metal or any electrically conductive material. For example, metals used in the present solution can include aluminum, copper, titanium, tungsten, silver, gold, rhuthenium, or any other metal. For the purposes of the present solution, in addition to metals, source/drain contacts or gate metals can also include other electrically conductive materials, such as highly doped semiconductors, for example.

The present solution can additionally or alternatively utilize 2D materials for forming transistor channels. 2D materials can include, for example, but are not limited to, WS2, WSe2, WTe2, MoS2, MoSe2, MoTe2, HfS2, ZrS2, and TiS2, GaSe, InSe, phosphorene, and other similar materials. These materials can be deposited by an atomic layer deposition (ALD) process and may be about 5-15 angstroms thick, the thinness lending to their name—2D material. 2D material layer can, depending on the material and design, have a broader range of thicknesses, such as between 0.2 nm and 3 nm. 2D materials may be annealed during or after the device formation process to recrystallize or grow the crystals and thereby improve electrical characteristics. 2D materials, for example, can be electrically conductive.

Additionally or alternatively, other semiconductive-behaving materials may be used, such as semiconductive behaving oxides. The semiconductive behaving material can be “turned off” and set to have a low or practically no off-state leakage current, but can be “turned on” and become highly conductive when voltage is applied. Example materials to create an n-type channel for example include, but are not limited to, In₂O₃, SnO₂, In GaZnO, and ZnO. Example materials that can be used to create a p-type channel may be formed utilizing, for example, SnO. These materials may be further doped to improve the electrical characteristics. These materials may also be referred to as conductive oxides for the purposes of this discussion.

As 2D materials can have a very large mobility, the 2D materials can be herein described as one embodiment, however it is to be appreciated that other non-epitaxially grown materials can be utilized. Since a 2D material can be precisely deposited on an insulative sheet, this can enable a very low Dt integration build of horizontal nanosheets with high performance. Advantageously, any base substrate material can be utilized as no epitaxial growth is required and the base substrate can be removed for further stacking of the devices.

Carrier nanosheets can be used to provide support for the 2D material layers. Carrier nanosheets can include dielectric materials or semiconductor materials on which 2D material layer, such as a monolayer of 2D material, can be deposited, grown or otherwise formed. Carrier nanosheets can include an electrically insulating material that can be used as a seed layer for the 2D material(s) used in the stack. Additionally or alternatively, a seed layer can include a material that can be deposited onto a carrier nanosheet, onto which a layer of 2D material can be formed, deposited, or otherwise applied.

Reference will now be made to the Figures, which for the convenience of visualizing the 3D semiconductor fabrication techniques described herein, illustrate a substrate undergoing a process flow. Unless expressly indicated otherwise, each Figure represents one (or a set) of fabrication steps in a process flow for manufacturing the devices described herein. In the views of the Figures, connections between conductive layers or materials may or may not be shown. However, these connections between various layers and masks are merely illustrative and are intended to show a capability for providing such connections, and the connections should not be considered limiting to the scope of the claims. Conversely, when example illustrations do not show electrical connections to components that are electrically contacted, it is understood that such electrical connections can be made as understood by a person of ordinary skill.

Although the Figures and aspects of the disclosure may show or describe devices herein as having a particular shape, such shapes are used as examples of the present solution and are merely illustrative and should not be considered limiting to the scope of the techniques described herein. For example, although most of the Figures show various layers in a rectangular shaped configuration, other shapes are also contemplated, and indeed the techniques described herein may be implemented in any shape or geometry. In addition, examples in which two transistors or devices are shown stacked on top of one another are shown for illustrative purposes only, and for the purposes of simplicity. Indeed, the techniques described herein may provide for one to any number N stacked devices. Likewise, the techniques described herein may provide for one to any number N nanosheets. Further, although the devices fabricated using these techniques are shown to form transistors integrated with capacitors, it should be understood that any type of electric electronic device may be manufactured using such techniques, including but not limited to transistors, variable resistors, resistors, capacitors, memory components, logic gates and components and any other components known or used in the art.

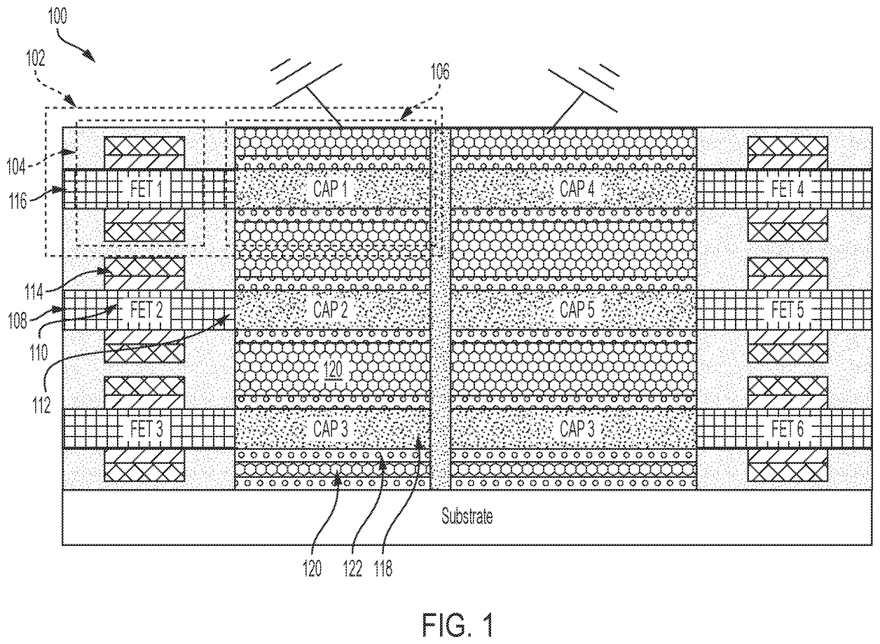

FIG. 1 shows a memory device 100 comprising a plurality of memory elements 102 according to one implementation. The memory element is a device that includes a transistor 104 and a capacitor 106. The transistor includes a source region 108, a channel region 110, a drain region 112 and a gate component 114 on at least one side of the channel region 110 between the source region 108 and drain region 112. The channel region 110 is formed in a first portion of a nanosheet 116. The capacitor has a first capacitor component 118 and second capacitor component 120 separated by an insulator 122 in which the first capacitor component 118 is provided in a second portion of the nanosheet. The memory device 100 may be provided with additional memory elements 102 in a horizontal or vertically stacked arrangement to provide an array of memory elements 102, which may be operated together or may be controlled independently. The example shown includes six memory elements 102.

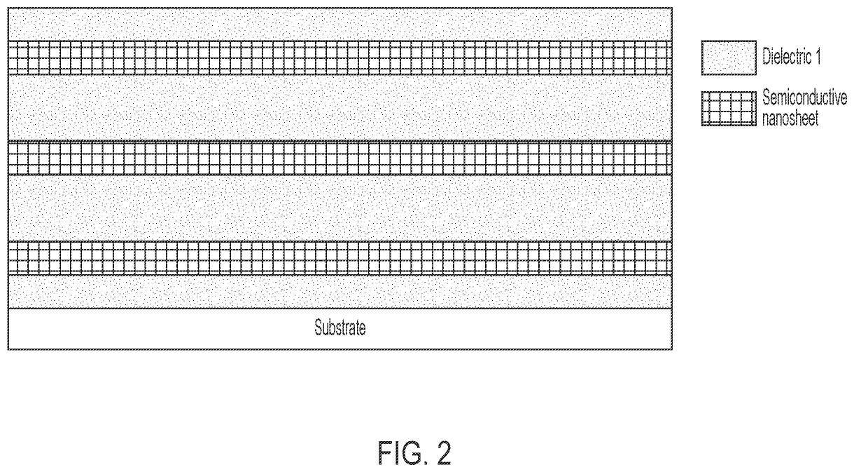

FIG. 2 shows a stage of device formation in which a stack of layers is provided with one or more nanosheet layers having a first dielectric layer on one or both sides. In the example shown, a substrate may comprise a semiconductor, insulator, conductor, or combination of any of these types of materials. In the case of a semiconductor substate, a dielectric may be deposited after which alternating layers of silicon (e.g., polysilicon) and additional dielectric layers may be formed. The number of layers of silicon is selected based on the number of memory elements desired in a given vertical stack.

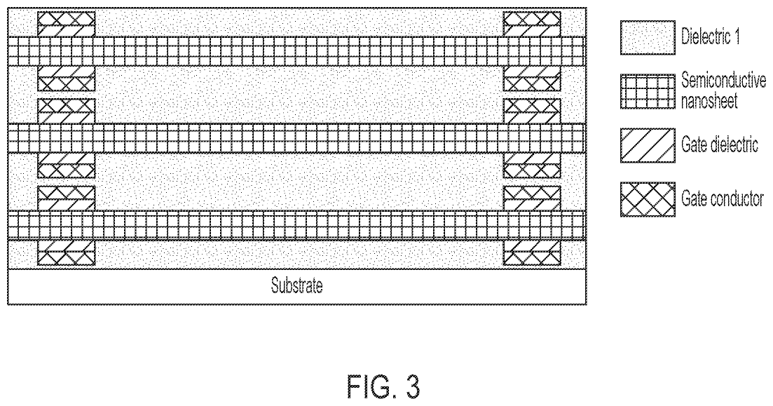

FIG. 3 shows a stage of the device formation in which a nanosheet is defined from the nanosheet layer and a transistor component is formed utilizing a first portion of the nanosheet. In this portion of the device formation process, a gate dielectric and gate conductor are formed in a manner described elsewhere and, thus, not detailed here. For example, certain steps are shown in U.S. patent application Ser. No. 17/672,643 filed Feb. 15, 2022.

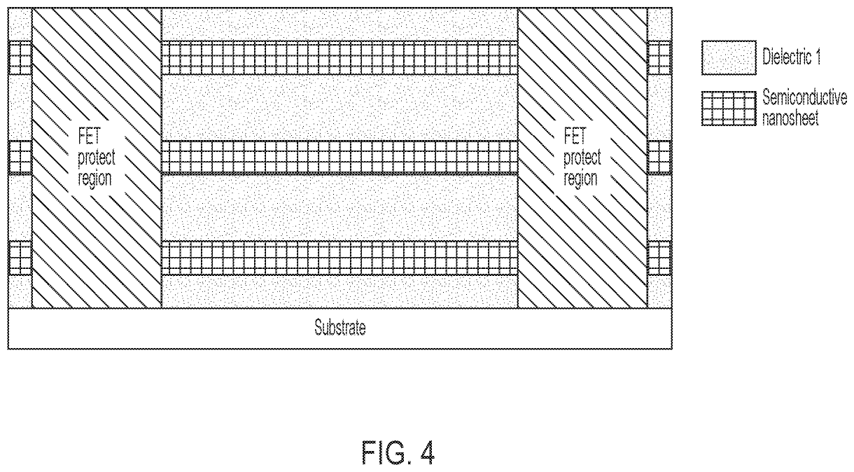

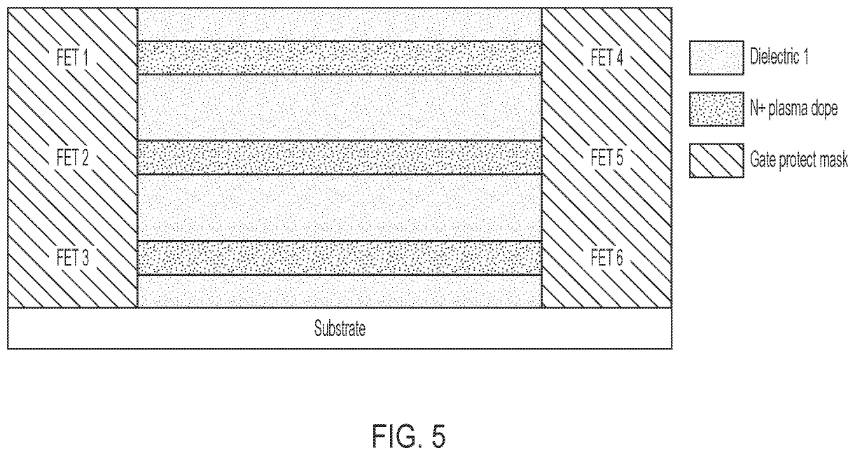

FIG. 4 shows a stage of the device formation in which each transistor is protected to leave exposed a second portion of the nanosheet. FIG. 5 shows a stage of the device formation in which the nanosheet is doped to be either n doped or p doped. Similar steps of masking a gate region and doping an intrinsic layer are shown in U.S. patent application Ser. No. 17/975,352 filed Oct. 27, 2022.

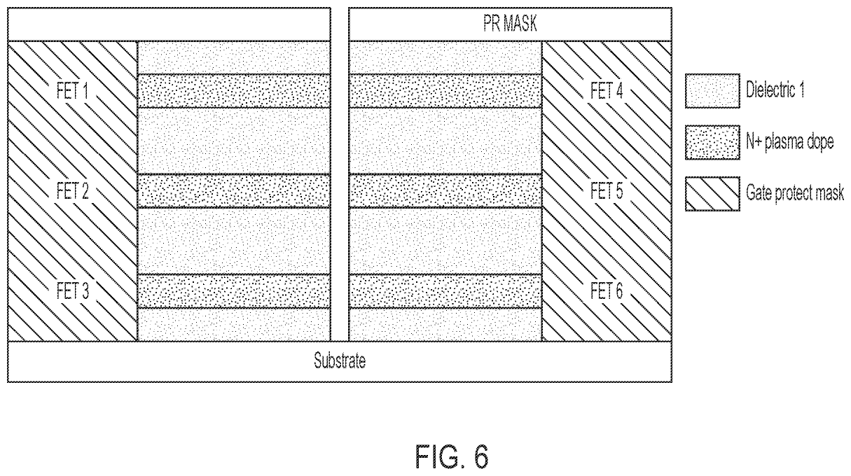

FIG. 6 shows a stage of the device formation in which a mask is provided to allow a portion of the nanosheet layers and dielectric layers to be etched.

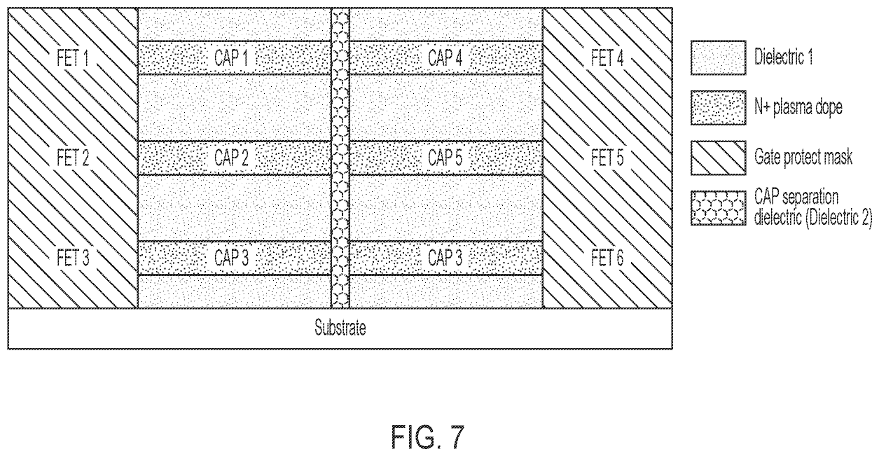

FIG. 7 shows a stage of the device formation in which a second dielectric layer is formed in the etched opening to separate each nanosheet into two sections as well as provide support for the nanosheet during subsequent steps.

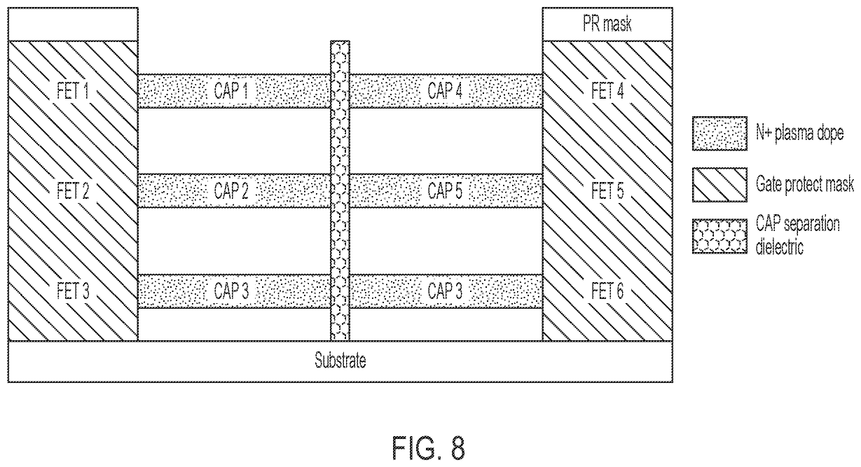

FIG. 8 shows a stage of the device formation in which the first dielectric layer on one or more sides of the one or more nanosheets is removed.

It should be noted that while FIG. 5 shows the dopant being introduced before the first dielectric layer is removed (in FIG. 8), dopant introduction could instead be performed after the first dielectric is removed. In such a case, more of each nanosheet would advantageously be exposed at the time of introduction as the first dielectric layer would not be covering portions of the nanosheet.

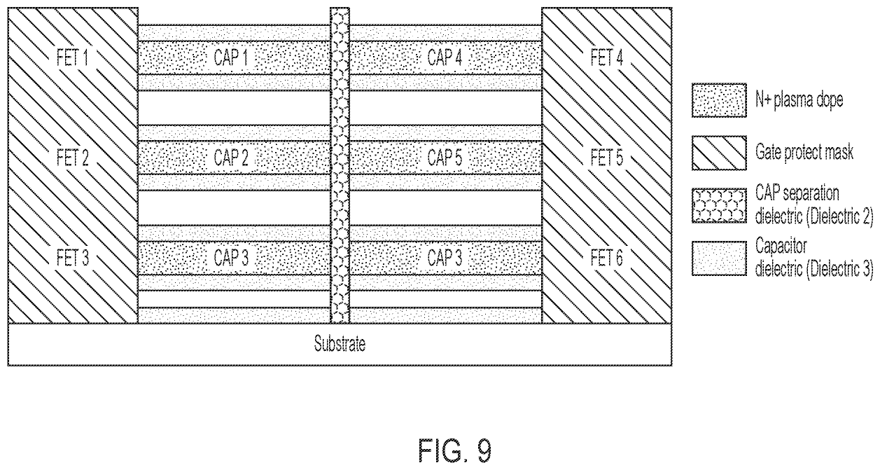

FIG. 9 shows a stage of the device formation in which a third dielectric layer is formed on opposing sides of the one or more nanosheets. The third dielectric layer may be provided on one, two or more sides of the nanosheet. The characteristics of the third dielectric layer, such as dielectric constant and thickness may be selected to yield an optimal capacitor dielectric.

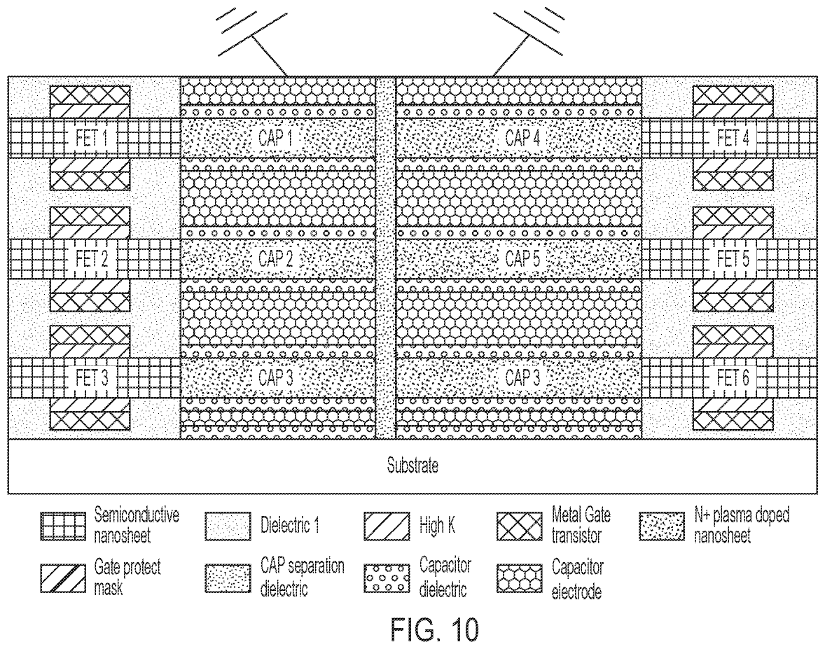

FIG. 10 shows a stage of the device formation in which a conductive layer, such as a metal layer, is formed on the third dielectric layer thereby finishing the capacitor component of the memory element. As shown. the conductive layer may span multiple capacitors of the various memory elements and may be coupled to ground.

1. A memory element comprising:
a transistor including a channel, a source region, a drain region and a gate component on at least one side of the channel between the source region and drain region, the channel provided in a first portion of a nanosheet; and
a capacitor having a first capacitor component and second capacitor component separated by an insulator, the first capacitor component provided in a second portion of the nanosheet.

2. The memory element of claim 1, wherein the second capacitor component extends to another memory element.

3. The memory element of claim 1, wherein the second capacitor component is coupled to ground.

4. The memory element of claim 1, wherein the first portion of the nanosheet has a different doping characteristic than the second portion of the nanosheet.

5. A memory device comprising:
a first memory element including a transistor provided in a first portion of a first nanosheet and a capacitor component provided in a second portion of the first nanosheet; and
a second memory element including a transistor provided in a first portion of a second nanosheet and a capacitor component provided in a second portion of the second nanosheet.

6. The memory device of claim 5, wherein the capacitor of the first memory element is coupled to the capacitor of the second memory element.

7. The memory device of claim 5, wherein the memory device is formed over a substrate and wherein the first memory element is laterally adjacent the second memory element relative to the substrate.

8. The memory device of claim 5, wherein the device is formed over a substrate and wherein the first memory element is vertically adjacent the second memory element relatively to the substrate.

9. A method comprising:
providing a nanosheet;
forming a transistor component utilizing a first portion of the nanosheet; and
forming a capacitor component utilizing a second portion of the nanosheet.

10. The method of claim 9, wherein forming the capacitor comprises:
masking the transistor,
doping the second portion of the nanosheet to render it more conductive than the first portion of the nanosheet,
depositing a dielectric, and
depositing a conductive material separated from the second portion of the nanosheet by the dielectric.

11. The method of claim 9 wherein after providing the nanosheet, the method further comprises forming a dielectric to separate the nanosheet into a first region and second region, and wherein the transistor component is formed in a first portion of the first region of the nanosheet while a second transistor is formed in a first portion of the second region of the nanosheet.

12. The method of claim 11 wherein the capacitor component is formed in a second portion of the first region of the nanosheet while a second capacitor is formed in a second portion of the second region of the nanosheet.
